(19) United States
(12) Patent Application Publication
(10) Pub. No.: US 2010/0178773 A1
(43) Pub. Date: Jul. 15, 2010

(54) METHOD OF FORMING SEMICONDUCTOR DEVICES EMPLOYING DOUBLE PATTERNING

(75) Inventors: In-wook Oh, Suwon-si (KR); Nam-su Lim, Hwaseong-si (KR); Jong-sun Sel, Hwaseong-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/651,788

(22) Filed: Jan. 4, 2010

(30) Foreign Application Priority Data
Jan. 14, 2009 (KR) 10-2009-0003039

(51) Int. Cl. H01L 21/467

(52) U.S. Cl. 438/703; 257/E21.486

(57) ABSTRACT

A first material film is formed on a substrate. Linear second material film patterns are formed on the first material film. Spacer patterns are formed on sidewalls of the second material film patterns, and the second material film patterns are removed to expose portions of the first material film between the spacer patterns. The exposed portions of the first material film are removed to form first material film patterns. Third material film patterns are formed in trenches defined by the first material film patterns. Adjacent first portions of the second material film patterns proximate ends of the second material film patterns are separated by a distance less than twice a width of the individual spacer patterns. In some embodiments, the distance separating the adjacent first portions of the second material film patterns is greater than a minimum feature size, and a width of the individual spacer patterns is approximately equal to the minimum feature size.

### CROSS-REFERENCE TO RELATED APPLICATIONS

This application claims the benefit of Korean Patent Application No. 10-2009-0003039, filed on Jan. 14, 2009, in the Korean Intellectual Property Office, the disclosure of which is incorporated herein in its entirety by reference.

### BACKGROUND

The inventive subject matter relates to methods for forming semiconductor devices and, more particularly, to methods of forming fine features in semiconductor devices.

Finer patterns are generally desirable to increase integration density of semiconductor devices. Although there has been a dramatic reduction in design rules for fabrication of semiconductor devices, the ability to form fine patterns may be limited by resolution limits associated in a photolithography operation for forming the patterns required for embodying the semiconductor device, and more particularly, for forming line and space patterns.

### SUMMARY

Some embodiments of the inventive subject matter provide methods of forming semiconductor devices. A first material film is formed on a substrate. Linear second material film patterns are formed on the first material film. Spacer patterns are formed on sidewalls of the second material film patterns, and the second material film patterns are removed to expose portions of the first material film between the spacer patterns. The exposed portions of the first material film are removed to form first material film patterns. Third material film patterns are formed in trenches defined by the first material film patterns. Adjacent first portions of the second material film patterns proximate ends of the second material film patterns are separated by a distance less than twice a width of the individual spacer patterns. In some embodiments, the distance separating the adjacent first portions of the second material film patterns is greater than a minimum feature size, and a width of the individual spacer patterns is approximately equal to the minimum feature size.

In further embodiments, the second material film patterns further include parallel second portions, and adjacent ones of the second portions of the second material film patterns are separated by a distance is greater than twice the width of the individual spacer patterns. The width of the individual spacer patterns may be approximately a minimum feature size, the distance between the adjacent second portions of the second material patterns may be approximately three times the minimum feature size and the distance between the adjacent first portions of the second material film patterns may be greater than the minimum feature size and less than twice the minimum feature size.

In additional embodiments, forming linear second material film patterns on the first material film may include forming parallel line patterns, wherein a distance between adjacent ones of the line patterns is greater than twice the width of the individual spacer patterns, and forming an assistant pattern disposed such that a distance between the assistant pattern and at least one end of each of the line patterns is less than twice the width of each of the spacer patterns. A width of the individual spacer patterns may be approximately a minimum feature size, a distance between adjacent ones of the line patterns may be approximately three times the minimum feature size, and the distance between the assistant pattern and the at least one end of each of the line patterns may be greater than the minimum feature size and less than twice the minimum feature size. Forming linear second material film patterns on the first material film may further includes forming a protrusion proximate the at least one end of each of the line patterns.

In further embodiments, methods of forming a semiconductor device include forming a first material film on a substrate, forming parallel linear second material film patterns on the first material film, forming spacer patterns on sidewalls of the second material film patterns to leave parallel exposed first linear portions of the first material film between spacer patterns formed on adjacent ones of the second material film patterns, removing the second material film patterns to expose second linear portions of the first material film between the spacer patterns, removing the first and second exposed portions of the first material film to form first material film patterns and forming parallel linear third material film patterns in trenches defined by the first material film patterns, wherein adjacent ones of the parallel linear third material film patterns are separated by a distance approximately equal to a width of the individual spacer patterns. The second material film patterns may have a width of approximately a minimum feature size and may be separated by a distance approximately three times the minimum feature size, and the individual spacer patterns may have a width of approximately the minimum feature size. Removing the first and second exposed portions of the first material film to form first material film patterns may include etching the first and second exposed portions of the first material film using the spacer patterns as an etching mask.

### BRIEF DESCRIPTION OF THE DRAWINGS

Exemplary embodiments of the inventive subject matter will be more clearly understood from the following detailed description, taken in conjunction with the accompanying drawings in which:

FIGS. 1, 4, 7, 10, and 13 are plane views for describing a method of forming a semiconductor device according to some embodiments of the inventive subject matter;

FIGS. 2, 5, 8, 11, and 14 are cross-sectional views taken along a line A-A′ of FIGS. 1, 4, 7, 10, and 13, respectively;

FIGS. 3, 6, 9, 12, and 15 are cross-sectional views taken along a line B-B′ of FIGS. 1, 4, 7, 10, and 13, respectively;

FIGS. 16, 19, 22, and 25 are plane views for describing a method of forming a semiconductor device, according to further embodiments of the inventive subject matter;

FIGS. 17, 20, 23 and 26 are cross-sectional views taken along a line A-A′ of FIGS. 16, 19, 22, and 25, respectively;

FIGS. 18, 21, 24, and 27 are cross-sectional views taken along a line B-B′ of FIGS. 16, 19, 22, and 25, respectively; and

FIGS. 28 through 31 are plane views of various modifications of semiconductor devices, according to embodiments of the inventive subject matter with reference to FIGS. 16 through 27.

### DETAILED DESCRIPTION

Some embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A method of forming a semiconductor device according to the inventive subject matter may be used to fabricate various fine electronic devices. Examples of the fine electronic devices may include high-integrated circuit semiconductor memory devices such as a Dynamic Random Access Memory (DRAM), a Static Random Access Memory (SRAM), a flash memory device, etc., processors such as a central processor unit (CPU), a digital signal processor (DSP), a CPU/DSP combined processor, etc., an application specific integrated circuit (ASIC), a micro electro mechanical device, an optoelectronic device, and a display device. However, the fine electronic devices stated above are merely examples.

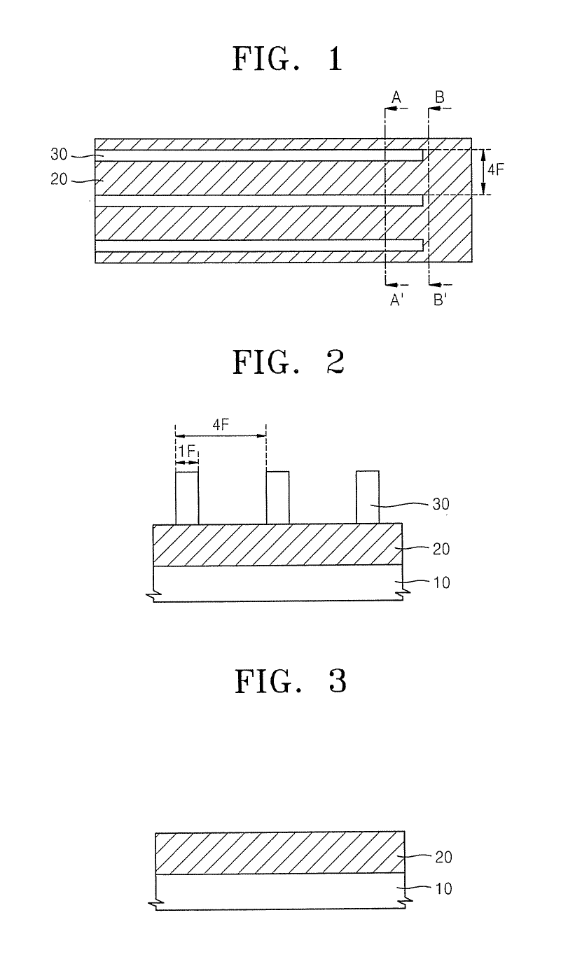

FIGS. 1, 4, 7, 10, and 13 are plane views illustrating operations for forming a semiconductor device according to some embodiments of the inventive subject matter. FIGS. 2, 5, 8, 11, and 14 are cross-sectional views taken along a line A-A′ of FIGS. 1, 4, 7, 10, and 13, respectively, and FIGS. 3, 6, 9, 12, and 15 are cross-sectional views taken along a line B-B′ of FIGS. 1, 4, 7, 10, and 13, respectively.

First, referring to FIGS. 1 through 3, a first material film 20 is formed on a base film 10. The base film 10 may be a semiconductor substrate. Alternatively, the base film 10 may be a film formed on a semiconductor substrate. Second material film patterns 30 are formed on the first material film 20.

The second material film pattern 30 may be line patterns that are parallel to each other. The width of each of the second material film patterns 30 may be a minimum feature size 1F, for example. A minimum feature size refers to the width of the smallest line in a semiconductor fabricating operations of a semiconductor device. The interval between adjacent second material film patterns 30 may be 3F, which is 3 times the minimum feature size 1F. Therefore, a pitch of the second material film patterns 30, which is the sum of the width of each of the second material film patterns 30 and the interval between the adjacent second material film patterns 30, may be 4F, which is 4 times the minimum feature size 1F.

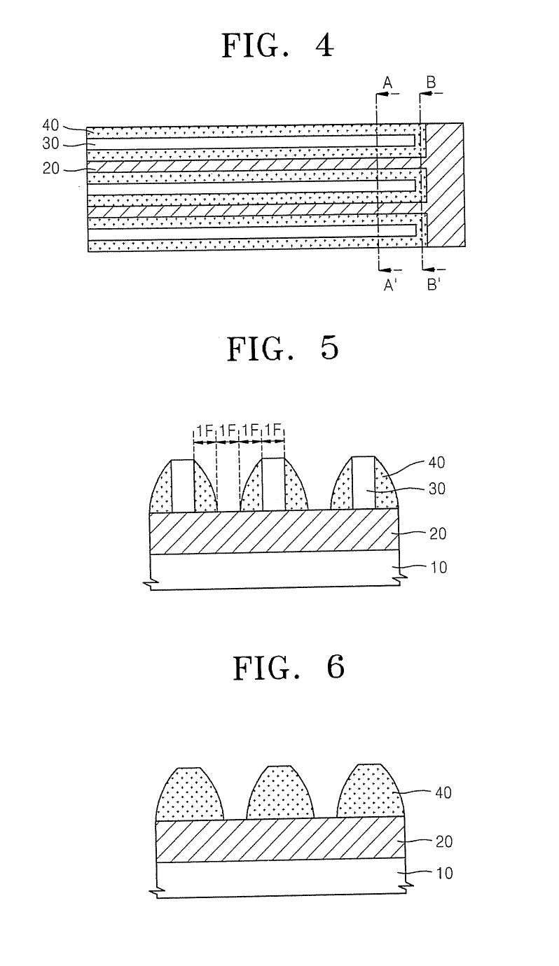

Next, referring to FIGS. 4 through 6, spacer patterns 40 are formed on sidewalls of the second material film patterns 30. The spacer patterns 40 are, for example, formed by depositing a film formed of an appropriate material onto the second material film patterns 30 and performing etchback process thereto. Since a method of forming the spacer patterns 40 by performing etchback process is well known to those of ordinary skill in the art, detailed descriptions thereof will be omitted. The width of each of the spacer patterns 40 may be 1F. Here, the width of each of the spacer patterns 40 refers to a horizontal width as shown in FIG. 5. If the interval between the adjacent second material film patterns 30 is 3F, the width of a portion of the first material film 20 exposed by the second material film patterns 30 and the spacer patterns 40 may be 1F. The spacer patterns 40 are formed to surround the sidewalls of the second material film patterns 30, and thus, the spacer patterns 40 are continuously connected without being separated at each end of the second material film patterns 30 (refer to FIG. 6).

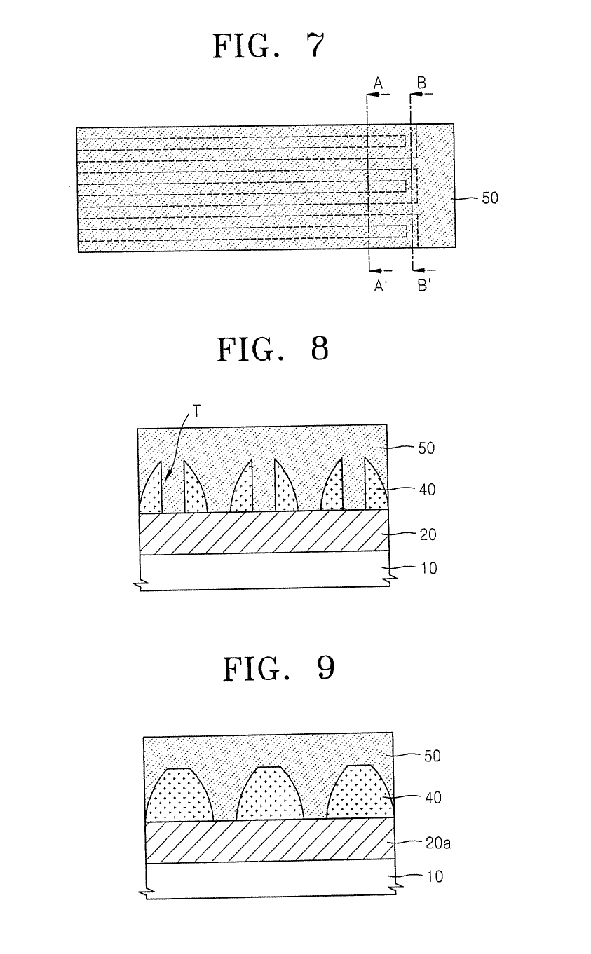

Next, referring to FIGS. 7 through 9, the second material film patterns 30 are removed first, and then, a photoresist film 50 is formed to completely cover the first material film 20 and the spacer patterns 40. Next, referring to FIGS. 10 through 12, the photoresist film 50 is partially removed to form a photoresist film pattern 50′ which covers parts of the space patterns 40 that were covering the sidewalls of the second material film patterns 30, the ends of the spacer patterns 40, which correspond to the ends of the second material film patterns 30, and a part of the first material film 20. The first material film 20 is etched using exposed portions of the spacer patterns 40 by the photoresist film pattern 50′ as an etching mask, and thus, first material film patterns 20a are formed.

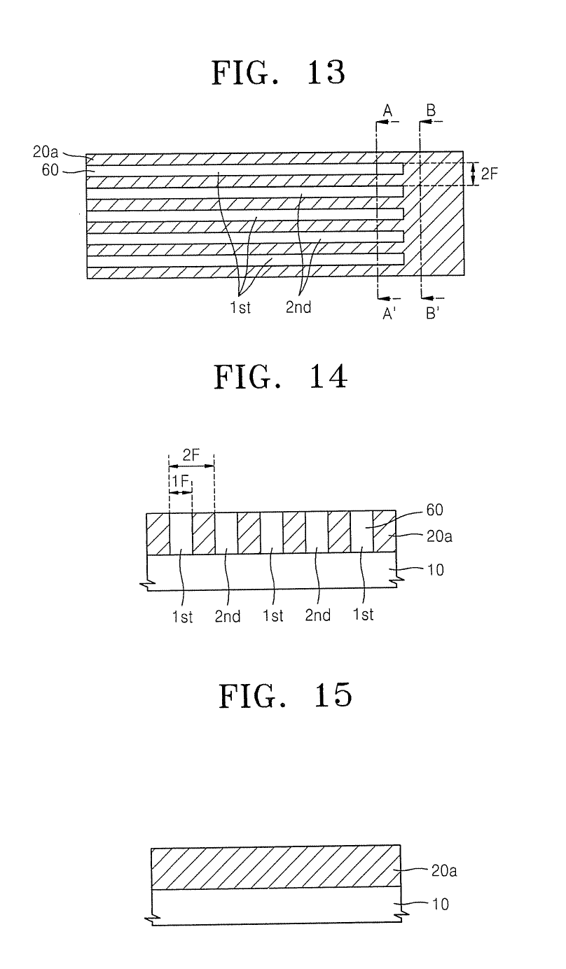

Next, referring to FIGS. 13 through 15, the photoresist film pattern 50′ and the spacer patterns 40 are removed, and a third material film (not shown) is deposited to completely cover the first material film patterns 20a and the base film 10. Then, the third material film is partially flattened using a method such as chemical mechanical polishing (CMP) to form third material film patterns 60 such that the top surfaces of the first material film patterns 20a and the third material film patterns 60 are flush with each other. As a result, the third material film patterns 60 fills trenches defined by the first material film patterns 20a. Next, the first material film patterns 20a are removed, and thus, the third material film patterns 60, which are formed as line patterns with a predetermined interval between each other, are formed. For example, the third material film patterns 60 are formed as line patterns, wherein the width of each of the line patterns is 1F, and the line patterns may be at least 1F apart from each other.

The third material film patterns 60 are formed as first target patterns (indicated as ‘1st’ in FIGS. 13 and 14) and second target patterns (indicated as ‘2nd’ in FIGS. 13 and 14). The first target patterns are formed in regions corresponding to the second material film patterns 30; whereas the second target patterns are formed in regions corresponding to the portions of the first material film 20 exposed by the spacer patterns 40 prior to the removal of the second material film patterns 30. The second target patterns are not connected to each other, and each of them forms an individual pattern.

According to the method of forming a semiconductor device described above in reference to FIGS. 1 through 15, fine line patterns can be formed, wherein the width of each of the fine line patterns is 1F, and the fine line patterns are 1F apart from each other.

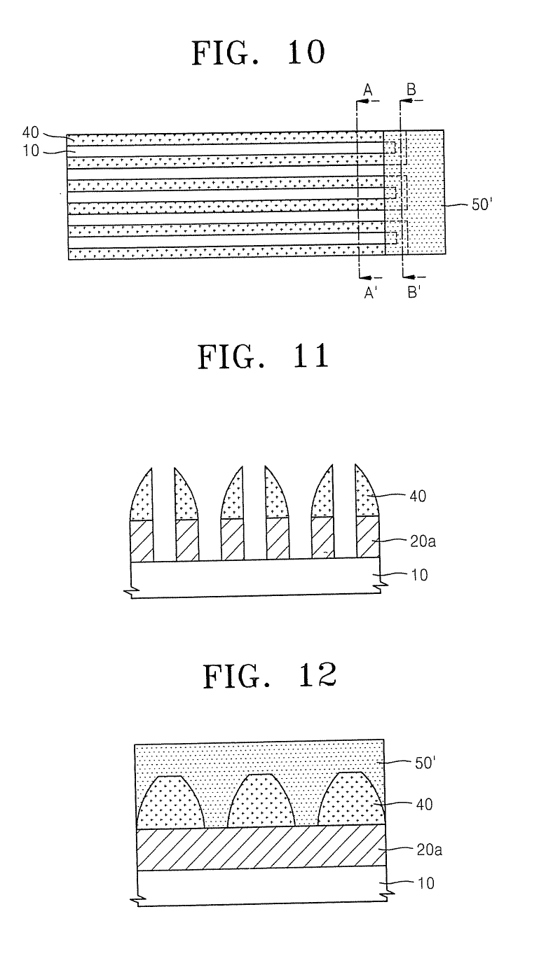

If the formation of the photoresist film pattern 50′ shown in FIGS. 10 and 12 is omitted, the second target patterns in the third material film patterns 60 are formed to be connected to each other, and thus individual patterns would not be formed. In other words, it is necessary to additionally perform the formation of the photoresist film pattern 50′ to form the third material film patterns 60 consisting of individual line patterns that are apart from each other. Thus, for simplification of operations, other embodiments of the inventive subject matter will be described below.

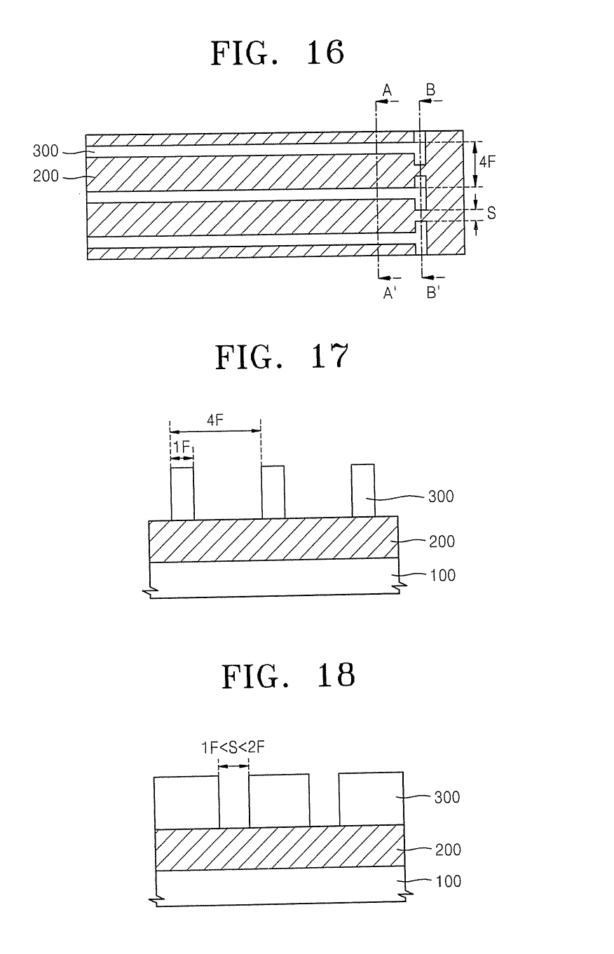

FIGS. 16, 19, 22, and 25 are plane views for describing a method of forming a semiconductor device, according to further embodiments of the inventive subject matter. FIGS. 17, 20, 23 and 26 are cross-sectional views taken along a line A-A′ of FIGS. 16, 19, 22, and 25, respectively, and FIGS. 18, 21, 24, and 27 are cross-sectional views taken along a line B-B′ of FIGS. 16, 19, 22, and 25, respectively.

First, referring to FIGS. 16 through 18, a first material film 200 is formed on a base film 100. The base film 100 may be a semiconductor substrate. Alternatively, the base film 100 may be a film formed on the semiconductor substrate. Second material film patterns 300 are formed on the first material film 200.

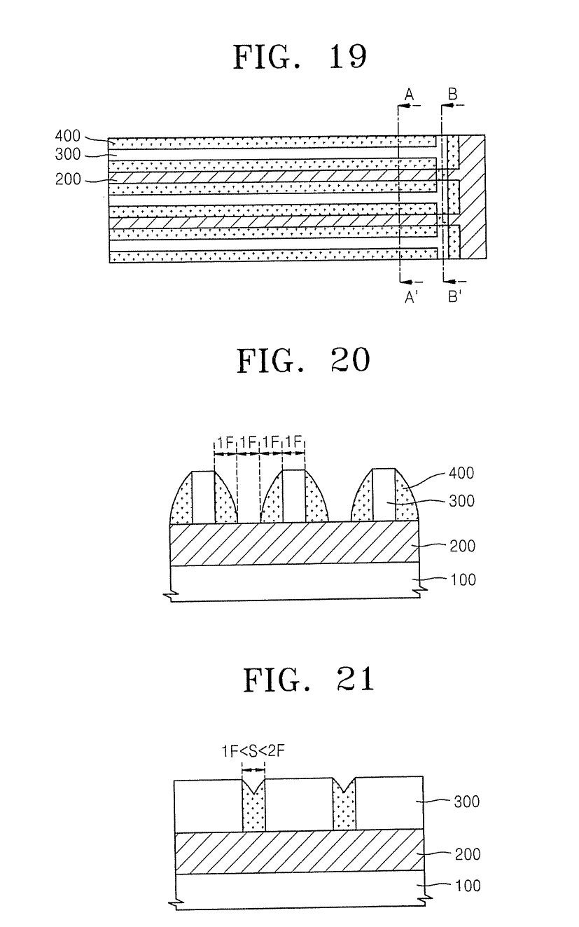

Next, referring to FIGS. 19 through 21, spacer patterns 400 are formed on sidewalls of the second material film patterns 300. The spacer patterns 400 are, for example, formed by depositing a film formed of an appropriate material onto the second material film patterns 300 and performing etchback process thereto. Since a method of forming the spacer patterns 400 by performing etchback process is well known to those of ordinary skill in the art, detailed descriptions thereof will be omitted.

At least some of the second material film patterns 300 may be disposed such that a minimum separation interval S therebetween is narrower than twice the width of each of the spacer patterns 400. The width of each of the spacer patterns 400 refers to a horizontal width shown in FIG. 20. Therefore, spaces between ends of the second material film patterns 300 that are adjacent to each other are completely filled by the spacer patterns 400, and thus, the first material film 200 is not exposed. For example, the second material film patterns 300 are disposed such that the minimum separation interval S between the ends of the second material film patterns 300 that are adjacent to each other is greater than 1F and less than 2F; whereas the spacer patterns 400 are disposed on the sidewalls of the second material film patterns 300 such that the width of each of the spacer patterns 400 is 1F. As a result, spaces between the ends of the second material film patterns 300 that are adjacent to each other are filled by the spacer patterns 400, and thus, the first material film 200 is not exposed.

The second material film patterns 300 are formed as line patterns and protrusions. The line patterns are disposed such that the line patterns are parallel to each other and are apart from each other by the distance which is greater than twice the width of the spacer patterns 400 (For example, each of the line patterns is apart from each other by the distance 3F). Each of the protrusions is formed on at least one end of each of the line patterns.

For example, in case where the line patterns are disposed such that the width of each of the spacer patterns 400 is 1F, the interval between the line patterns that are adjacent to each other is 3F, and the minimum separation interval S between the ends of the second material film patterns 300 that are adjacent to each other is greater than 1F and less than 2F, referring to FIG. 20, portions of the first material film 200 are exposed between the line patterns even after the spacer patterns 400 are formed on the sidewalls of the second material film patterns 300 (e.g. the line patterns), wherein the width of each of the exposed portions of the first material film 200 is 1F. However, referring to FIG. 21, another portions of the first material film 200 are not exposed between the ends of the second material film patterns 300 (e.g. the protrusions) that are adjacent to each other (refer to FIG. 21).

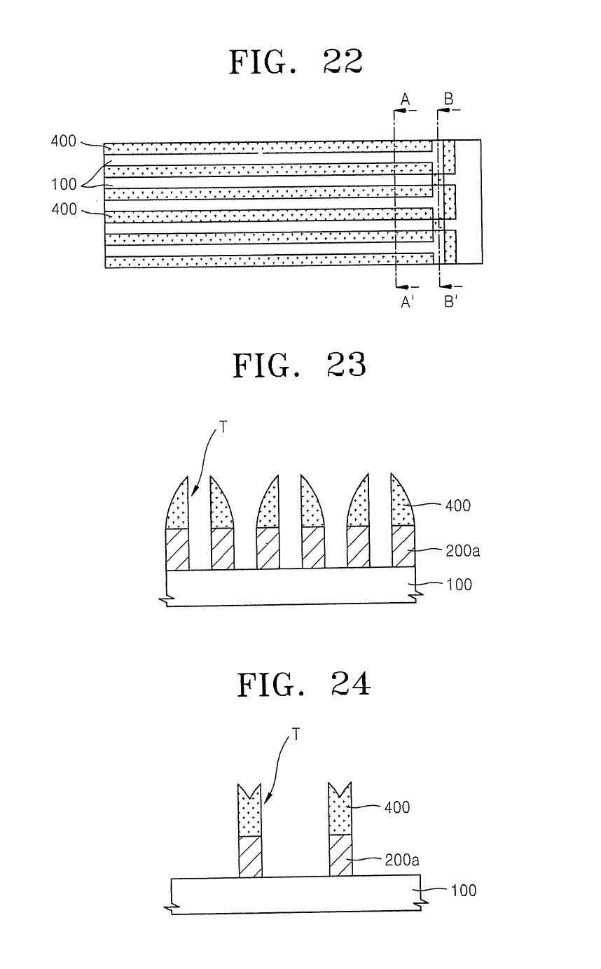

Next, referring to FIGS. 22 through 24, the second material film patterns 300 are removed, and the exposed portions of the first material film 200 are etched using the spacer patterns 400 as a mask to form first material film patterns 200a. The first material film 200 below the spacer patterns 400 remains, because the spacer patterns 400 are used as an etching mask. The exposed portions of the first material film 200 may be etched until the base film 100 is exposed.

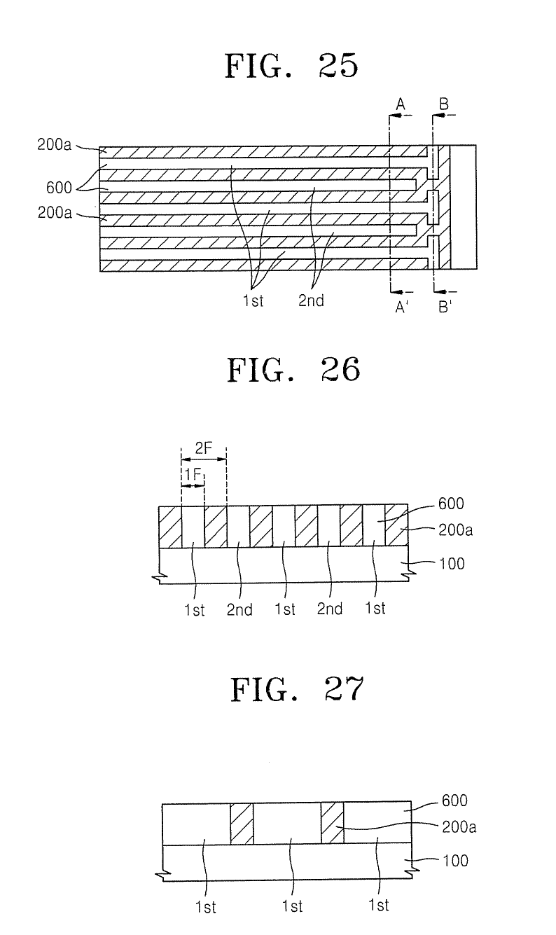

Next, referring to FIGS. 25 through 27, the spacer patterns 400 are removed, and third material film patterns 600 that fill spaces (trenches) between the first material film patterns 200a are formed. The third material film patterns 600 are formed of first target patterns (indicated as ‘1st’ in FIGS. 25 and 26) and second target patterns (indicated as ‘2nd’ in FIGS. 25 and 26). The first target patterns are formed in regions corresponding to the second material film patterns 300; whereas the second target patterns are formed in regions corresponding to the portions of the first material film 200 exposed by the spacer patterns 400 prior to the removal of the second material film patterns 300.

For example, in case where the line patterns are disposed such that the width of each of the spacer patterns 400 is 1F, the interval between the line patterns that are adjacent to each other is 3F, and the minimum separation interval S between the ends of the second material film patterns 300 that are adjacent to each other is greater than 1F and less than 2F, the second target patterns of the third material film patterns 600 are not connected to each other, and each of the second target patterns forms an individual pattern. In this case, as compared to the method of forming a semiconductor device described above in reference to FIGS. 1 through 15, it is not necessary to additionally form the photoresist film 50′, and thus, overall operations can be simplified.

The second material film patterns 300 and the spacer patterns 400 may be formed of materials that have etching selectivity with one another, the first material film 200 and the spacer patterns 400 may be formed of materials that have etching selectivity with one another, and the first material film 200 and the third material film patterns 600 may be formed of materials that have etching selectivity with one another. In the detailed description of embodiments of the inventive subject matter, ‘having etching selectivity’ means that the etch rates of two materials are significantly different from each other when the two materials are simultaneously etched under appropriate etching conditions.

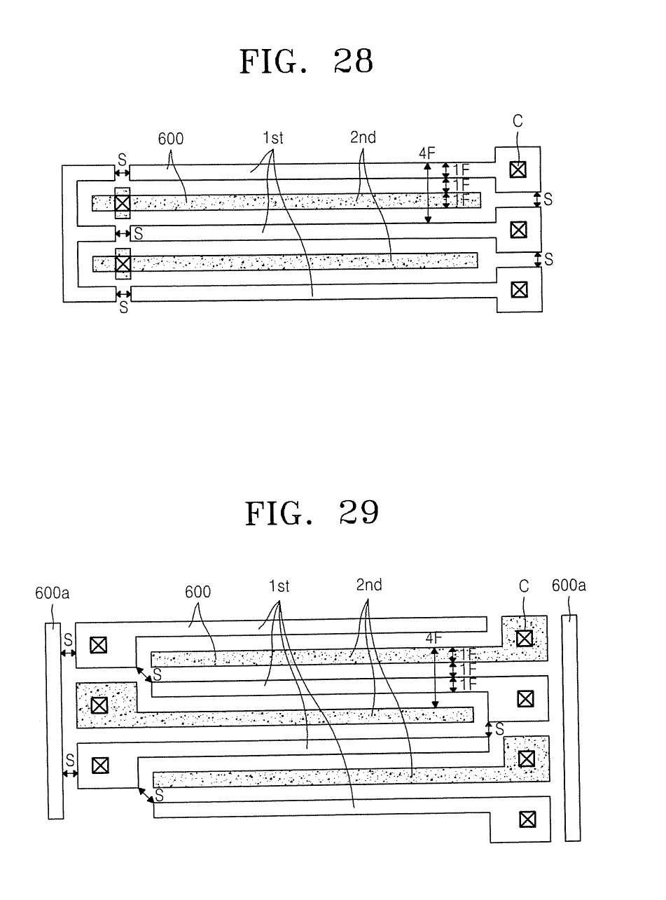

FIGS. 28 through 31 are plane views of various modifications of semiconductor devices, according to embodiments of the inventive subject matter with reference to FIGS. 16 through 27. Like reference numerals refer to like elements throughout

First, referring to FIG. 28, a semiconductor fine pattern in which the third material film patterns 600 (corresponding to 600 in FIGS. 16 through 27) are formed lastly is shown. The third material film patterns are formed of first target patterns (indicated as ‘1st’ in FIG. 28) and second target patterns (indicated as ‘2nd’ in FIG. 28). The first target patterns are formed in regions corresponding to the second material film patterns (corresponding to 300 in FIGS. 16 through 27); whereas the second target patterns are formed in regions corresponding to the portions of the first material film (corresponding to 200 in FIGS. 16 through 27) exposed by the spacer patterns (corresponding to 400 in FIGS. 16 through 27) prior to the removal of the second material film patterns. The second target patterns are not connected to each other, and each of them forms an individual pattern. Contact patterns C are formed at ends of the first target patterns and the second target patterns, wherein the ends of the first target patterns at which the contact patterns C are formed and the ends of the second target patterns at which the contact patterns C are formed are on opposite sides.

Protrusions are formed at the ends of the first target patterns on which the contact patterns C are formed, wherein the width of each of the protrusions is greater than the width of each of the line patterns. The minimum separation interval S between the protrusions of the first target patterns that are adjacent to each other is less than twice the width of each of the spacer patterns. Thus, the ends of the second target patterns are not connected to each other, and each of the second target patterns form an individual pattern.

No protrusions are formed at other ends of the first target patterns. However, since an assistant pattern (an E-shaped pattern at the left side of FIG. 28) is disposed such that the minimum separation interval S between the other ends of the first target patterns is less than twice the width of each of the spacer patterns, the other ends of the second target patterns are also not connected to each other, and each of the second target patterns form an individual pattern.

Referring to FIG. 29, a semiconductor fine pattern in which the third material film patterns 600 (corresponding to 600 in FIGS. 16 through 27) are formed lastly is shown. The third material film patterns 600 are formed of first target patterns (indicated as ‘1st’ in FIG. 29) and second target patterns (indicated as ‘2nd’ in FIG. 29). The first target patterns are formed in regions corresponding to the second material film patterns (corresponding to 300 in FIGS. 16 through 27); whereas the second target patterns are formed in regions corresponding to the portions of the first material film (corresponding to 200 in FIGS. 16 through 27) exposed by the spacer patterns (corresponding to 400 in FIGS. 16 through 27) prior to the removal of the second material film patterns. The second target patterns are not connected to each other, and each of them forms an individual pattern. Contact patterns C are formed at ends of the first target patterns and the second target patterns, wherein the contact patterns C are formed alternately at the ends of the first target patterns and the second target patterns, and the ends of the first target patterns at which the contact patterns C are formed and the ends of the second target patterns at which the contact patterns C are formed are on opposite sides.

Protrusions are formed respectively at the ends the first target patterns at which the contact patterns C are formed, wherein the width of each of the protrusions is greater than the width of each of the line patterns. So, for example, a contact C is formed on the right end of a first target pattern, and another contact C is formed on the left end of another first target patter; hence in an alternate form. An assistant pattern 600a is disposed such that the minimum separation interval S between the ends of the first target patterns is less than twice the width of each of the spacer patterns. Thus, the second target patterns are not connected to each other, and each of the second target patterns form an individual pattern.

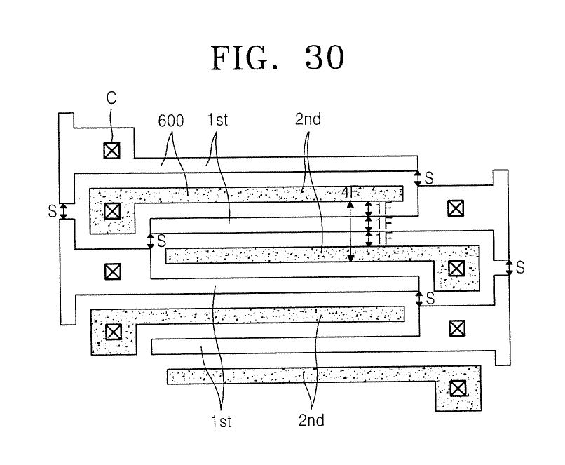

Referring to FIG. 30, a semiconductor fine pattern in which the third material film patterns 600 (corresponding to 600 in FIGS. 16 through 27) are formed lastly is shown. The third material film patterns 600 are formed of first target patterns (indicated as ‘1st’ in FIG. 30) and second target patterns (indicated as ‘2nd’ in FIG. 30). The first target patterns are formed in regions corresponding to the second material film patterns (corresponding to 300 in FIGS. 16 through 27); whereas the second target patterns are formed in regions corresponding to the portions of the first material film (corresponding to 200 in FIGS. 16 through 27) exposed by the spacer patterns (corresponding to 400 in FIGS. 16 through 27) prior to the removal of the second material film patterns. The second target patterns are not connected to each other, and each of them forms an individual pattern. Contact patterns C are formed at ends of the first target patterns and the second target patterns, wherein the contact patterns C are formed alternately at the ends of the first target patterns and the second target patterns, and the ends of the first target patterns at which the contact patterns C are formed and the ends of the second target patterns at which the contact patterns C are formed are on opposite sides.

Protrusions are formed at some of the right ends and some of the left ends of the first target patterns, wherein the width of each of the protrusions is greater than the width of each of the line patterns. Here, the protrusions are formed such that the minimum separation interval S between the ends of the first target patterns is less than twice the width of each of the spacer patterns. Thus, the second target patterns are not connected to each other, and each of the second target patterns form an individual pattern.

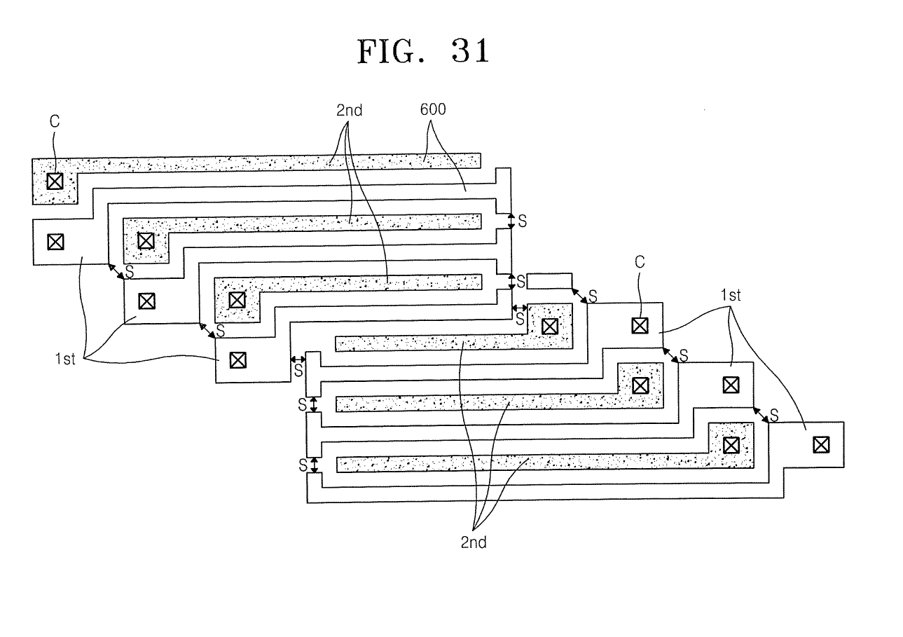

Referring to FIG. 31, a semiconductor fine pattern in which the third material film patterns 600 (corresponding to 600 in FIGS. 16 through 27) are formed lastly is shown. The third material film patterns 600 are formed of first target patterns (indicated as ‘1st’ in FIG. 31) and second target patterns (indicated as ‘2nd’ in FIG. 31). The first target patterns are formed in regions corresponding to the second material film patterns (corresponding to 300 in FIGS. 16 through 27); whereas the second target patterns are formed in regions corresponding to the portions of the first material film (corresponding to 200 in FIGS. 16 through 27) exposed by the spacer patterns (corresponding to 400 in FIGS. 16 through 27) prior to the removal of the second material film patterns. The second target patterns are not connected to each other, and each of them forms an individual pattern. Contact patterns C are formed alternately at some ends of the first target patterns and the second target patterns, wherein the ends of the first target patterns at which the contact patterns C are formed and the ends of the second target patterns at which the contact patterns C are formed are on opposite sides every 3 (or a greater multiple of 3) ends of the first target patterns and the second target patterns. Although not illustrated in FIG. 31, the ends of the first target patterns at which the contact patterns C are formed and the ends of the second target patterns at which the contact patterns C are formed may be on opposite sides every 4 (or a greater multiple of 4) ends or every 5 (or a greater multiple of 5) ends of the first target patterns and the second target patterns.

Protrusions are formed at some of the right ends and some of the left ends of the first target patterns, wherein the width of each of the protrusions is greater than the width of each of the line patterns. Here, the protrusions are formed such that the minimum separation interval S between the ends of the first target patterns is less than twice the width of each of the spacer patterns. Thus, the second target patterns are not connected to each other, and each of the second target patterns form an individual pattern. An assistant pattern (not shown) is formed such that the minimum separation interval S between each of the ends of the first target patterns and each of the assistant patterns is less than twice the width of each of the spacer patterns. Thus, the second target patterns are not connected to each other, and each of the second target patterns form an individual pattern.

According to the method of forming a semiconductor device according to the inventive subject matter, fine line patterns of a semiconductor device may be formed with simpler operations than the operations with respect to FIGS. 1 through 15.

While the inventive subject matter has been particularly shown and described with reference to exemplary embodiments thereof, it will be understood that various changes in form and details may be made therein without departing from the spirit and scope of the following claims.

What is claimed is:

1. A method of forming a semiconductor device, the method comprising:
forming a first material film on a substrate;
forming linear second material film patterns on the first material film;
forming spacer patterns on sidewalls of the second material film patterns;
removing the second material film patterns to expose portions of the first material film between the spacer patterns;
removing the exposed portions of the first material film to form first material film patterns; and
forming third material film patterns in trenches defined by the first material film patterns,
wherein adjacent first portions of the second material film patterns proximate ends of the second material film patterns are separated by a distance less than twice a width of the individual spacer patterns.

2. The method of claim 1, wherein the distance separating the adjacent first portions of the second material film patterns is greater than a minimum feature size, and wherein a width of the individual spacer patterns is approximately equal to the minimum feature size.

3. The method of claim 1, wherein the second material film patterns further comprise parallel second portions, wherein adjacent ones of the second portions of the second material film patterns are separated by a distance is greater than twice the width of the individual spacer patterns.

4. The method of claim 3, wherein the width of the individual spacer patterns is approximately a minimum feature size, wherein the distance between the adjacent second portions of the second material patterns is approximately three times the minimum feature size and wherein the distance between the adjacent first portions of the second material film patterns is greater than the minimum feature size and less than twice the minimum feature size.

5. The method of claim 1, wherein forming linear second material film patterns on the first material film comprises:
forming parallel line patterns, wherein a distance between adjacent ones of the line patterns is greater than twice the width of the individual spacer patterns; and
forming an assistant pattern disposed such that a distance between the assistant pattern and at least one end of each of the line patterns is less than twice the width of each of the spacer patterns.

6. The method of claim 5, wherein a width of the individual spacer patterns is approximately a minimum feature size, wherein a distance between adjacent ones of the line patterns is approximately three times the minimum feature size, and wherein the distance between the assistant pattern and the at least one end of each of the line patterns is greater than the minimum feature size and less than twice the minimum feature size.

7. The method of claim 5, wherein forming linear second material film patterns on the first material film further comprises forming a protrusion proximate the at least one end of each of the line patterns.

8. The method of claim 1, wherein forming third material film patterns in trenches defined by the first material film patterns forming first target patterns and second target patterns, wherein the first target patterns are formed in regions corresponding to the second material film patterns and the second target patterns are formed in regions corresponding to the portions of the first material film exposed by the spacer patterns prior to the removal of the second material film patterns, the second target patterns are not connected to each other, and each of the second target patterns forms an individual pattern.

9. The method of claim 1, further comprising:
removing the spacer patterns after forming the first material film patterns and prior to the forming of the third material film patterns; and
removing the first material film patterns after forming of the third material film patterns.

10. The method of claim 1, wherein the second material film patterns and the spacer patterns comprise materials providing etching selectivity with respect to one another.

11. The method of claim 1, wherein the first material film and the spacer patterns comprise providing etching selectivity with respect to one another.

12. The method of claim 1, wherein the first material film and the third material film patterns comprise materials providing etching selectivity with respect to one another.

13. The method of claim 1, wherein the second material film patterns and the spacer patterns comprise materials providing etching selectivity with respect to one another, and wherein the first material film and the third material film patterns comprise materials providing etching selectivity with respect to one another.

14. A method of forming a semiconductor device, the method comprising:
forming a first material film on a substrate;
forming parallel linear second material film patterns on the first material film;
forming spacer patterns on sidewalls of the second material film patterns to leave parallel exposed first linear portions of the first material film removing the second material film patterns to expose second linear portions of the first material film between the spacer patterns;
removing the first and second exposed portions of the first material film to form first material film patterns; and
forming parallel linear third material film patterns in trenches defined by the first material film patterns,
wherein adjacent ones of the parallel linear third material film patterns are separated by a distance approximately equal to a width of the individual spacer patterns.

15. The method of claim 14, wherein the second material film patterns have a width of approximately a minimum feature size and are separated by a distance approximately three times the minimum feature size, wherein the individual spacer patterns have a width of approximately the minimum feature size.

16. The method of claim 14, wherein removing the first and second exposed portions of the first material film to form first material film patterns comprises etching the first and second exposed portions of the first material film using the spacer patterns as an etching mask.

17. The method of claim 1, wherein forming parallel linear second material film patterns on the first material film comprises:
forming a second material film on the first material film; and
patterning the second material film to form the linear second material film patterns and end second material film patterns disposed perpendicularly at ends of the respective linear second material film patterns and separated from one another by a distance less than twice a width of the individual spacer patterns.
